(19) United States
(12) Patent Application Publication
(10) Pub. No.: US 2017/0290153 A1
(43) Pub. Date: Oct. 5, 2017

(54) CONNECTING STRUCTURE FOR PRINTED CIRCUIT BOARDS

(71) Applicant: KEEPER TECHNOLOGY CO., LTD., New Taipei City (TW)

(72) Inventors: Chih-Ming CHANG, New Taipei City (TW); Chiu-Mei LIAO, New Taipei City (TW)

(21) Appl. No.: 15/085,190

(22) Filed: Mar. 30, 2016

(51) Int. Cl. H05K 1/14; H05K 1/11

(52) U.S. Cl. CPC H05K 1/141; H05K 1/111

(57) ABSTRACT

A connecting structure for printed circuit boards has two printed circuit boards. At least one of the two printed circuit boards is a flexible printed circuit board, and each one of the two printed circuit boards has at least one connecting portion. The at least one connecting portion protrudes from an end of the printed circuit board, and is soldered on a top surface of the other printed circuit board. Each of the printed circuit boards is attached to the other printed circuit board only by a part (connecting portion), such that the solders on the connecting portion can extend forward and in two transverse directions beyond the connecting portion, thereby increasing the contact area between the solder and the top surface of the other printed circuit board. Therefore, the connecting structure can firmly connect two printed circuit boards and can enhance the resistance to pull.

### BACKGROUND OF THE INVENTION

### 1. Field of the Invention

The present invention relates to a connecting structure for two printed circuit boards, and at least one of the two printed circuit boards is a flexible printed circuit board.

### 2. Description of the Prior Arts

Conventionally, a flexible printed circuit board, which is bendable, is usually used for specially-designed LED lights. However, the flexible printed circuit board costs higher than a rigid printed circuit board. Thus, to save the cost, the flexible printed circuit board is usually cut into strips, and then two of the strips of the flexible printed circuit board are connected into a desired shape. Or one of the strips of the flexible printed circuit board and a striped rigid circuit board are connected into a desired shape.

However, with reference to FIG. 7, when the flexible printed circuit boards are connected in the conventional way, an end of one of the printed circuit boards 91 is directly soldered to a top surface of the other printed circuit board 92. Therefore, the solder 93 on the top printed circuit board 91 can contact the top surface of the bottom printed circuit board 92 only by extending forward from the end of the top printed circuit board 91. Thus, a contact area of the solder 93 is limited, and the connection between the printed circuit boards is not firm enough and is hard to resist pull. Consequently, the conventional connecting structure for flexible printed circuit boards needs to be improved.

To overcome the shortcomings, the present invention provides a connecting structure for printed circuit boards to mitigate or obviate the aforementioned problems.

### SUMMARY OF THE INVENTION

The main objective of the present invention is to provide a connecting structure for printed circuit boards that can enhance the resistance to pull.

The connecting structure for printed circuit boards has two printed circuit boards, at least one of the two printed circuit boards is a flexible printed circuit board, and each one of the two printed circuit boards has at least one connecting portion protruding from an end of said printed circuit board, and soldered on a top surface of the other printed circuit board.

Each one of the printed circuit boards is attached to the other printed circuit board only by a part (connecting portion), such that the solders on the connecting portion can extend forward and in two transverse directions beyond the connecting portion, thereby increasing the contact area between the solder and the top surface of the other printed circuit board. Therefore, the connecting structure can firmly connect two printed circuit boards and can enhance the resistance to pull.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a first embodiment of a connecting structure for printed circuit boards in accordance with the present invention;

FIG. 2 is an exploded perspective view of the connecting structure for printed circuit boards in FIG. 1;

FIG. 3 is a side view in partial section of the connecting structure for printed circuit boards in FIG. 1;

FIG. 4 is an end view in partial section of the connecting structure for printed circuit boards in FIG. 1;

FIG. 5 is a perspective view of a second embodiment of a connecting structure for printed circuit boards in accordance with the present invention;

FIG. 6 is a side view in partial section of a third embodiment of a connecting structure for printed circuit boards in accordance with the present invention; and

FIG. 7 is a perspective view of a conventional connecting structure for printed circuit boards in accordance with the prior art.

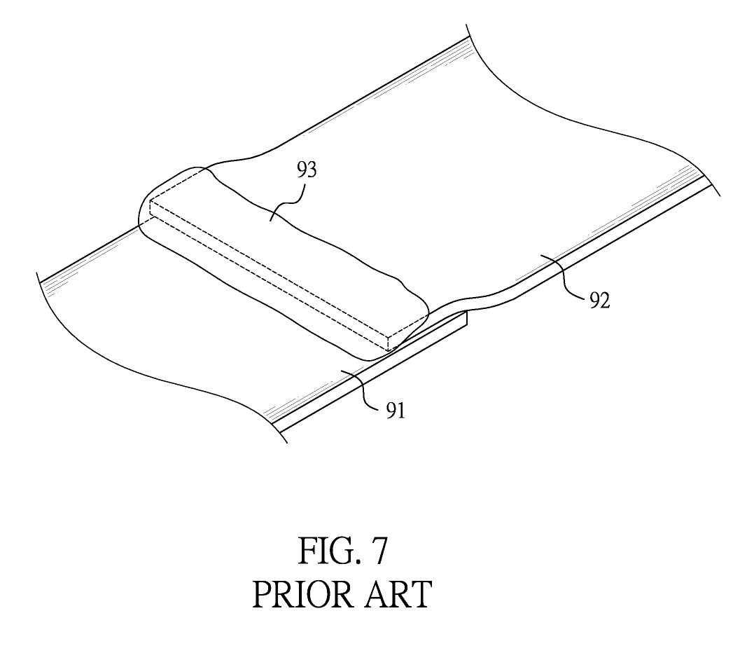

### DETAILED DESCRIPTION OF THE PREFERRED EMBODIMENTS

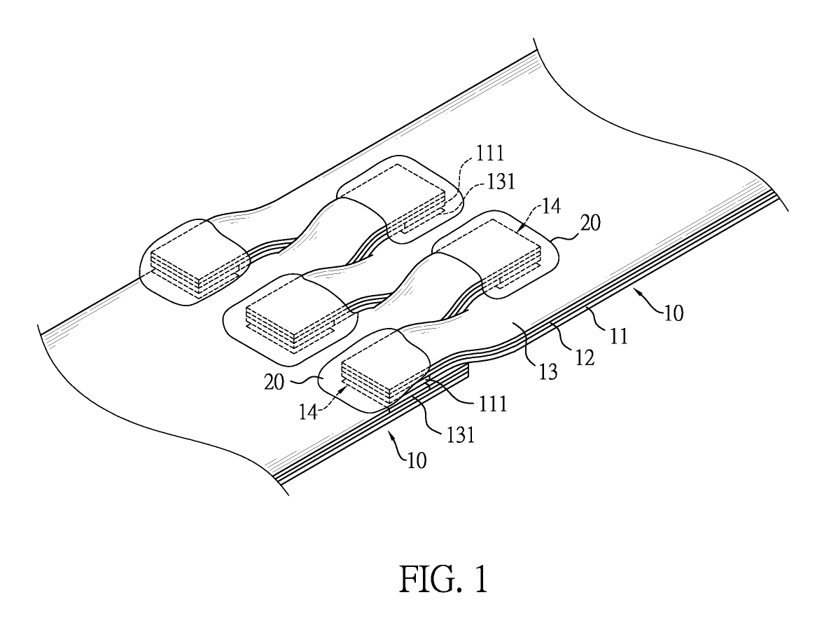

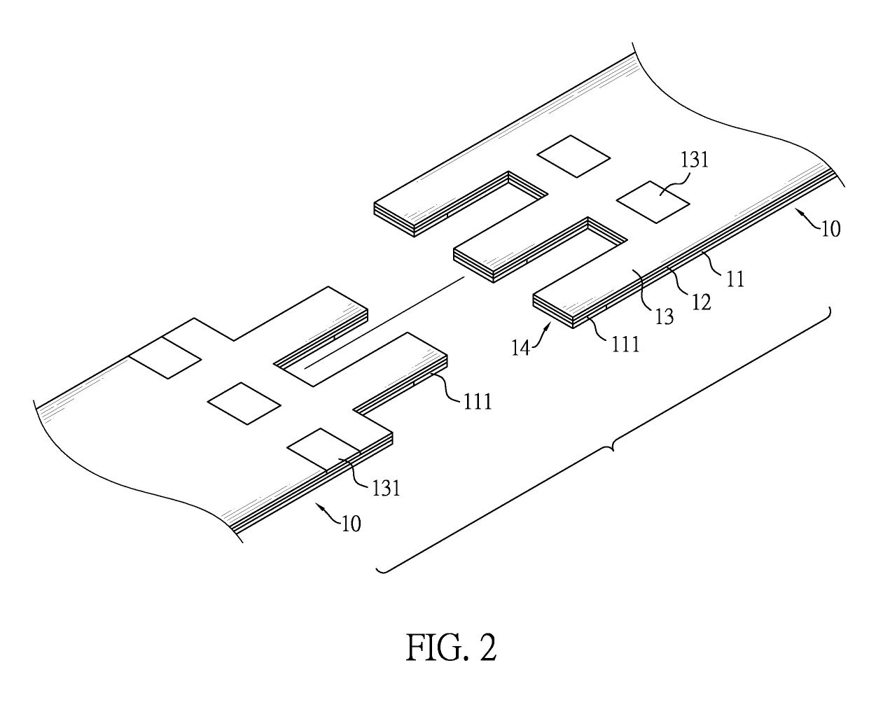

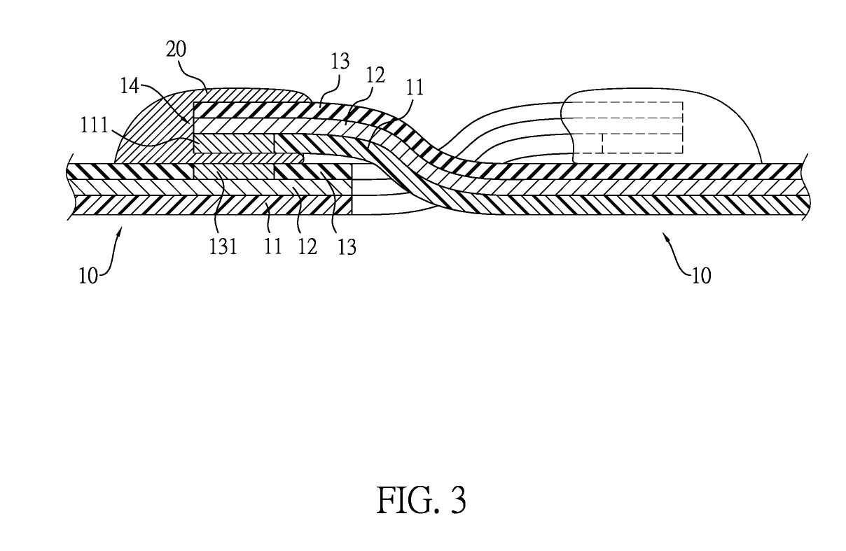

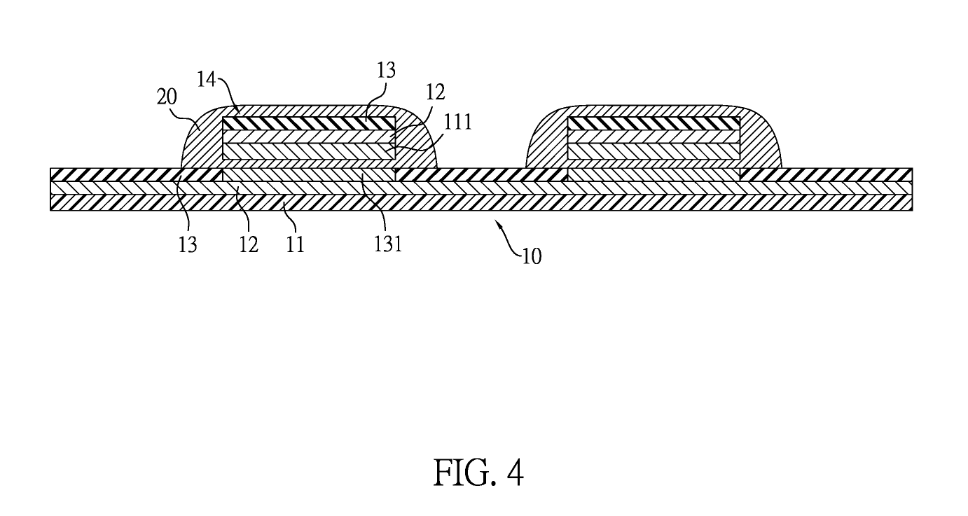

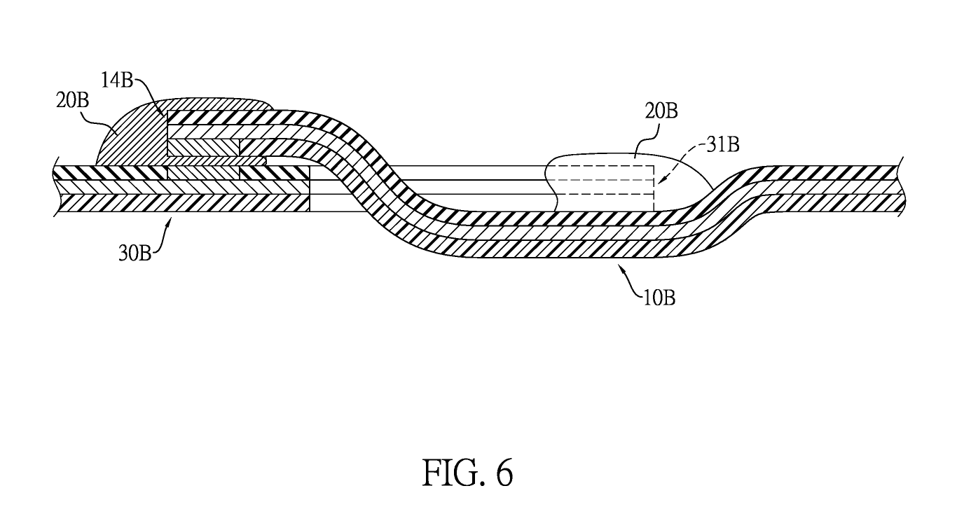

A connecting structure for printed circuit boards in accordance with the present invention comprises two printed circuit boards, which may be two flexible printed circuit boards or one flexible printed circuit board and one rigid printed circuit board. A first embodiment and a second embodiment in FIGS. 1 to 5 comprise two flexible printed circuit boards 10, 10A. A third embodiment in FIG. 6 comprises one flexible printed circuit board 10B and one rigid printed circuit board 30B.

With reference to FIGS. 1 to 4, in the first embodiment, each one of the two printed circuit boards 10 has a bottom insulated layer 11, a conductive layer 12, and a top insulated layer 13. The conductive layer 12 is mounted between the two insulated layers 11, 13. The bottom insulated layer 11 has multiple through holes and multiple bottom soldering pads 111. The bottom soldering pads 111 are respectively mounted in the through holes of the bottom insulated layer 11. The top insulated layer 13 has multiple through holes and multiple top soldering pads 131. The top soldering pads 131 are respectively mounted in the through holes of the top insulated layer 13. The conductive layer 12 is attached to the bottom soldering pads 111 and the top soldering pads 131. The conductive layer 12, the bottom soldering pads 111 and the top soldering pads 131 are all conductors.

In a preferred embodiment, the printed circuit boards 10 are preferably, but not limited to, elongated and striped. Each one of the printed circuit boards 10 has multiple connecting portions 14. The connecting portions 14 protrude from an end of the printed circuit board 10, and are spaced apart from each other. The connecting portions 14 extend curvedly into and are soldered on a top surface of the other printed circuited board 10. The connecting portions 14 of the two printed circuit boards 10 are arranged in a staggered manner. The bottom soldering pads 111 are disposed in the connecting portions 14, and correspond to the top soldering pads 131 of the other printed circuit board 10. Solder 20 wraps a top surface, a front surface, and both sides of one of the connecting portions 14, and extends into a portion between said connecting portion 14 and the top surface of the other printed circuit board 10. To be specific, the solder 20 is attached and soldered to the bottom soldering pad 111 of said connecting portion 14 and the corresponding top soldering pad 131. The conductive layer 12, the bottom soldering pads 111 and the top soldering pads 131 are all conductors and are attached to each other, such that the conductive layer 12 of the upper printed circuit board 10, the bottom soldering pad 111 of the upper printed circuit board 10, the top soldering pad 131 of the lower printed circuit board 10, and the conductive layer 12 of the lower printed circuit board 10 are electrically conducted in sequence. That is, the two printed circuit boards 10 are electrically connected.

When the two printed circuit boards 10 are in assembly, unmelted solders are put between the top soldering pad 131 of one of the printed circuit boards 10 and the corresponding bottom soldering pad 111 of the other printed circuit board 10. Then, the unmelted solders are heated indirectly and melted when the two printed circuit boards 10 are soldered by another solder 20, which still achieves the soldering.

Each one of the printed circuit boards 10 is attached to the other printed circuit board 10 only by a part (connecting portions 14), and the connecting portions 14 are arranged in a staggered manner, such that the solders 20 on the connecting portions 14 can extend forward and in two transverse directions beyond the connecting portion 14, thereby increasing the contact area between the solder 20 and the top surface of the other printed circuit board 10. Therefore, the connecting structure can firmly connect two printed circuit boards 10 and can enhance the resistance to pull.

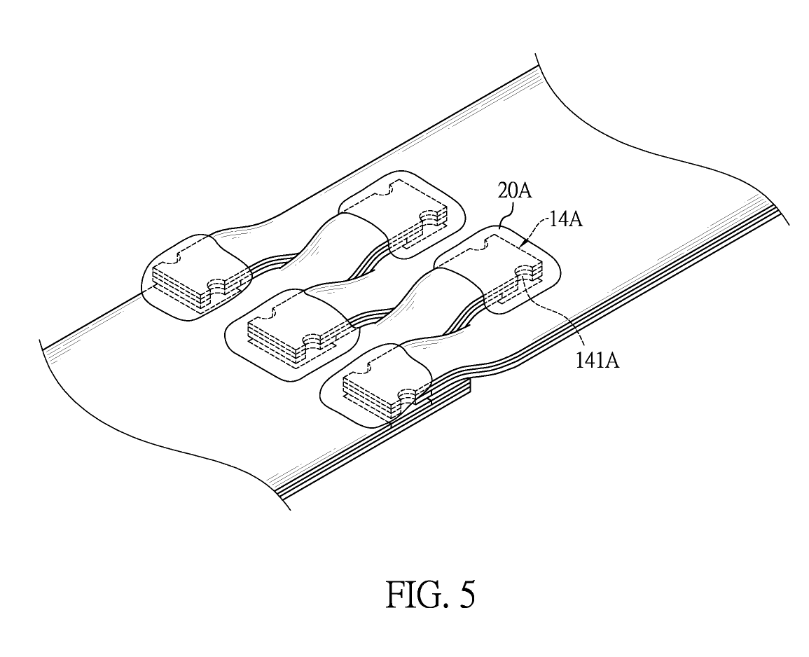

With reference to FIG. 5, the second embodiment of the present invention is substantially similar to the first embodiment mentioned above, but in the second embodiment, each one of the connecting portions 14A has two recesses 141A respectively formed in two sides of said connecting portion 14A to accommodate the solder 20A, thereby further enhancing the resistance to pull.

With reference to FIG. 6, the third embodiment of the present invention is substantially similar to the first embodiment mentioned above, but the second embodiment comprises a flexible printed circuit board 10B and a rigid printed circuit board 30B. The rigid printed circuit board 30B still has the connecting portion 31B, but the connecting portion 31B does not extend curvedly and is not bent upward. On the contrary, the flexible printed circuit board 10B is bent downward at a position adjacent to the connecting portion 14B to attach upward the connecting portion 31B of the rigid printed circuit board 30B. Then the connecting portion 14B of the flexible printed circuit board 10B is bent upward to attach downward the top surface of the rigid printed circuit board 30B. The third embodiment still can enhance the resistance to pull by increasing the contact area of the solder 20B.

In another embodiment, the solder may not wrap the top surface of the connecting portion, and is only disposed between the connecting portion and the top surface of the other printed circuit board. The solder still extends to the front surface and the both sides of the connecting portion, such that the solder is still firmly attached to the connecting portion to achieve the enhancement of the resistance to pull.

In another embodiment, the solder may not extend into the portion between the connecting portion and the top surface of the other printed circuit board, and only wraps the top surface, the front surface, and the both sides of the connecting portion, such that the solder is still firmly attached to the connecting portion to achieve the enhancement of the resistance to pull.

In another embodiment, the flexible printed circuit board or the rigid printed circuit board may be altered in other structures other than two insulated layers and a conductive layer.

In another embodiment, each one of the two printed circuit boards may have only one connecting portion. In this situation, the solder on the connecting portion still extends forward and in at least one transverse direction beyond the connecting portion, thereby increasing the contact area of the solder to enhance the resistance to pull.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A connecting structure for printed circuit boards comprising two printed circuit boards, wherein at least one of the two printed circuit boards is a flexible printed circuit board, and each one of the two printed circuit boards has at least one connecting portion protruding from an end of said printed circuit board, and soldered on a top surface of the other printed circuit board.

2. The connecting structure for printed circuit boards as claimed in claim 1, wherein solder extends into a portion between each one of the at least one connecting portion of each one of the two printed circuit boards and the top surface of the other printed circuit board.

3. The connecting structure for printed circuit boards as claimed in claim 2, wherein
each one of the at least one connecting portion of each one of the two printed circuit boards has
a bottom soldering pad mounted on a bottom surface of said connecting portion;
each one of the two printed circuit boards has
at least one top soldering pad mounted on the top surface of said printed circuit board, and corresponding to the bottom soldering pad of the at least one connecting portion of the other printed circuit board; and
the solder, which extends into the portion between each one of the at least one connecting portion of each one of the two printed circuit boards and the top surface of the other printed circuit board, is soldering to the bottom soldering pad of each one of the at least one connecting portion of each one of the two printed circuit boards and the corresponding top soldering pad.

4. The connecting structure for printed circuit boards as claimed in claim 1, wherein each one of the two printed circuit boards has
two insulated layers; and
a conductive layer mounted between the two insulated layers.

5. The connecting structure for printed circuit boards as claimed in claim 3, wherein each one of the two printed circuit boards has
two insulated layers, and each one of the two insulated layers has
at least one through hole accommodating the bottom soldering pad of the at least one connecting portion or the at least one top soldering pad; and
a conductive layer mounted between the two insulated layers and attached to the bottom soldering pad of the at least one connecting portion and the at least one top soldering pad.

6. The connecting structure for printed circuit boards as claimed in claim 1, wherein the solder wraps a top surface of the at least one connecting portion of each one of the two printed circuit boards.

7. The connecting structure for printed circuit boards as claimed in claim 5, wherein the solder wraps a top surface of the at least one connecting portion of each one of the two printed circuit boards.

8. The connecting structure for printed circuit boards as claimed in claim 1, wherein each one of the at least one connecting portion has
two recesses respectively formed in two sides of said connecting portion to accommodate the solder.

9. The connecting structure for printed circuit boards as claimed in claim 7, wherein each one of the at least one connecting portion has
two recesses respectively formed in two sides of said connecting portion to accommodate the solder.

10. The connecting structure for printed circuit boards as claimed in claim 1, wherein the at least one connecting portion is multiple in amount, the multiple connecting portions are spaced apart from each other, and the multiple connecting portions of the two printed circuit boards are arranged in a staggered manner.

11. The connecting structure for printed circuit boards as claimed in claim 9, wherein the at least one connecting portion is multiple in amount, the multiple connecting portions are spaced apart from each other, and the multiple connecting portions of the two printed circuit boards are arranged in a staggered manner.
